(19) United States
(12) Patent Application Publication
(10) Pub. No.: US 2015/0053909 A1
(43) Pub. Date: Feb. 26, 2015

(54) NONLINEAR MEMRISTORS

(71) Applicants: Jianhua Yang, Palo Alto, CA (US); Max Zhang, Mountain View, CA (US); Matthew D. Pickett, San Francisco, CA (US); R. Stanley Williams, Portola Valley, CA (US)

(72) Inventors: Jianhua Yang, Palo Alto, CA (US); Max Zhang, Mountain View, CA (US); Matthew D. Pickett, San Francisco, CA (US); R. Stanley Williams, Portola Valley, CA (US)

(73) Assignee: HEWLETT-PACKARD DEVELOPMENT COMPANY, LP., Houston, TX (US)

(21) Appl. No.: 14/385,259

(22) PCT Filed: Apr. 25, 2012
(86) PCT No.: PCT/US2012/035024

§ 371 Date: Sep. 15, 2014

(51) Int. Cl. H01L 27/24; H01L 45/00

(52) U.S. Cl. CPC H01L 27/2463; H01L 45/1233; H01L 45/1253; H01L 45/146; H01L 45/1608
USPC 257/4; 438/382

(57) ABSTRACT

A nonlinear memristor includes a bottom electrode, a top electrode, and an insulator layer between the bottom electrode and the top electrode. The insulator layer comprises a metal oxide. The nonlinear memristor further includes a switching channel within the insulator layer, extending from the bottom electrode toward the top electrode, and a nano-cap layer of a metal-insulator-transition material between the switching channel and the top electrode. The top electrode comprises the same metal as the metal in the metal-insulator-transition material.

### STATEMENT OF GOVERNMENT INTEREST

This invention has been made with government support. The government has certain rights in the invention.

### BACKGROUND

The continuous trend in the development of electronic devices has been to minimize the sizes of the devices. While the current generation of commercial microelectronics are based on sub-micron design rules, significant research and development efforts are directed towards exploring devices on the nano-scale, with the dimensions of the devices often measured in nanometers or tens of nanometers. In addition to the significant reduction of individual device size and much higher packing density as compared to microscale devices, nanoscale devices may also provide new functionalities due to physical phenomena on the nanoscale that are not observed on the micron scale.

For instance, electronic switching in nanoscale devices using titanium oxide as the switching material has recently been reported. The resistive switching behavior of such a device has been linked to the memristor circuit element theory originally predicted in 1971 by L. O. Chua. The discovery of the memristive behavior in the nanoscale switch has generated significant interest, and there are substantial on-going research efforts to further develop such nanoscale switches and to implement them in various applications. One of the many important potential applications is to use such a switching device as a memory unit to store digital data.

In order to be competitive with CMOS FLASH memories, the emerging resistive switches need to have a switching endurance that exceeds at least millions of switching cycles. Reliable switching channels inside the device may significantly improve the endurance of these switches. Different switching material systems are being explored to achieve memristors with desired electrical performance, such as high speed, high endurance, long retention, low energy and low cost.

### BRIEF DESCRIPTION OF THE DRAWINGS

FIGS. 1A-1C are each a side elevational view, depicting an example of a memristor device based on principles disclosed herein.

FIG. 2A, on coordinates of current (in A) and device voltage (in V), is a plot of switching current/voltage loops for the system Pt/TaOₓ/nanocap VO₂/V, in accordance with principles disclosed herein

FIG. 2B, on coordinates of current (in A) and device voltage (in V), is a plot of switching current/voltage loops for the system Pt/TaOₓ/nanocap VO₂/V, in accordance with principles disclosed herein.

FIG. 3A, on coordinates of current (in A) and device voltage (in V), is a plot of switching current/voltage loops for the system Pt/TaOₓ/nanocap NbO₂/Nb, in accordance with principles disclosed herein.

FIG. 3B, on coordinates of current (in A) and device voltage (in V), is a plot of switching current/voltage loops for the system Pt/TaOₓ/nanocap NbO₂/Nb, in accordance with principles disclosed herein.

FIG. 4 is a flow chart depicting an example method of forming a nonlinear memristor, in accordance with principles disclosed herein.

FIG. 5 is an isometric view of a nanowire crossbar architecture incorporating nonlinear electrical devices, in accordance with principles disclosed herein.

### DETAILED DESCRIPTION

Reference is now made in detail to specific examples of the disclosed nonlinear memristor and specific examples of ways for creating the disclosed nonlinear memristor. When applicable, alternative examples are also briefly described.

Nonlinear electrical devices do not exhibit a linear current/voltage (I/V) relationship. Examples of nonlinear electrical devices include diodes, transistors, some semiconductor structures, and other devices, such as memristors. Nonlinear electrical devices can be used in a wide variety of applications, including amplifiers, oscillators, signal/power conditioning, computing, memory, and other applications.

However, while memristors may typically exhibit nonlinearity in the high resistance state, their linear I/V characteristic in the low resistance state may limit their application, such as in large passive crossbar arrays.

As used in the specification and claims herein, the singular forms “a,” “an,” and “the” include plural referents unless the context clearly dictates otherwise.

As used in this specification and the appended claims, “approximately” and “about” mean a ±10% variance caused by, for example, variations in manufacturing processes.

In the following detailed description, reference is made to the drawings accompanying this disclosure, which illustrate specific examples in which this disclosure may be practiced. The components of the examples can be positioned in a number of different orientations and any directional terminology used in relation to the orientation of the components is used for purposes of illustration and is in no way limiting. Directional terminology includes words such as “top,” “bottom,” “front,” “back,” “leading,” “trailing,” etc.

It is to be understood that other examples in which this disclosure may be practiced exist, and structural or logical changes may be made without departing from the scope of the present disclosure. Therefore, the following detailed description is not to be taken in a limiting sense. Instead, the scope of the present disclosure is defined by the appended claims.

Memristors are nano-scale devices that may be used as a component in a wide range of electronic circuits, such as memories, switches, and logic circuits and systems. In a memory structure, a crossbar of memristors may be used. When used as a basis for memories, the memristor may be used to store a bit of information, 1 or 0. When used as a logic circuit, the memristor may be employed as configuration bits and switches in a logic circuit that resembles a Field Programmable Gate Array (FPGA), or may be the basis for a wired-logic Programmable Logic Array (PLA).

When used as a switch, the memristor may either be a closed or open switch in a cross-point memory. During the last few years, researchers have made great progress in finding ways to make the switching function of these memristors behave efficiently. For example, tantalum oxide (TaOₓ)-based memristors have been demonstrated to have superior endurance over other nano-scale devices capable of electronic switching. In lab settings, tantalum oxide-based memristors are capable of over 10 billion switching cycles whereas other memristors, such as tungsten oxide (WOₓ)- or titanium oxide (TiOₓ)-based memristors, may require a sophisticated feedback mechanism for avoiding over-driving the devices or an additional step of refreshing the devices with stronger voltage pulses in order to obtain an endurance in the range of 10 million switching cycles.

Memristor devices typically may comprise two electrodes sandwiching an insulating layer. One or more conducting channels in the insulating layer between the two electrodes may be formed that are capable of being switched between two states, one in which the conducting channel forms a conductive path between the two electrodes (“ON”) and one in which the conducting channel does not form a conductive path between the two electrodes (“OFF”).

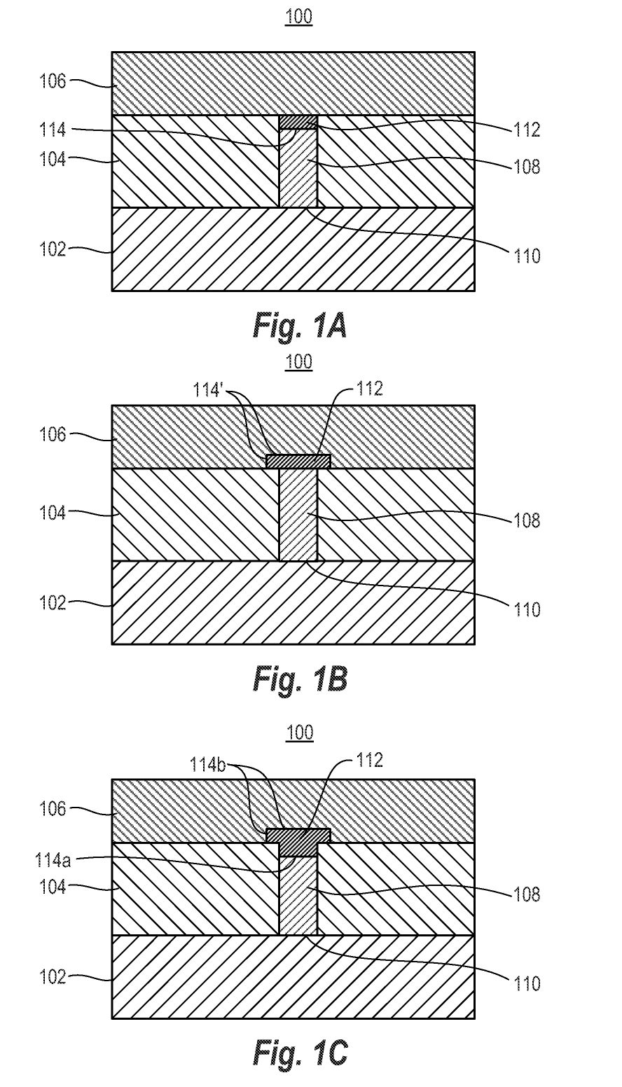

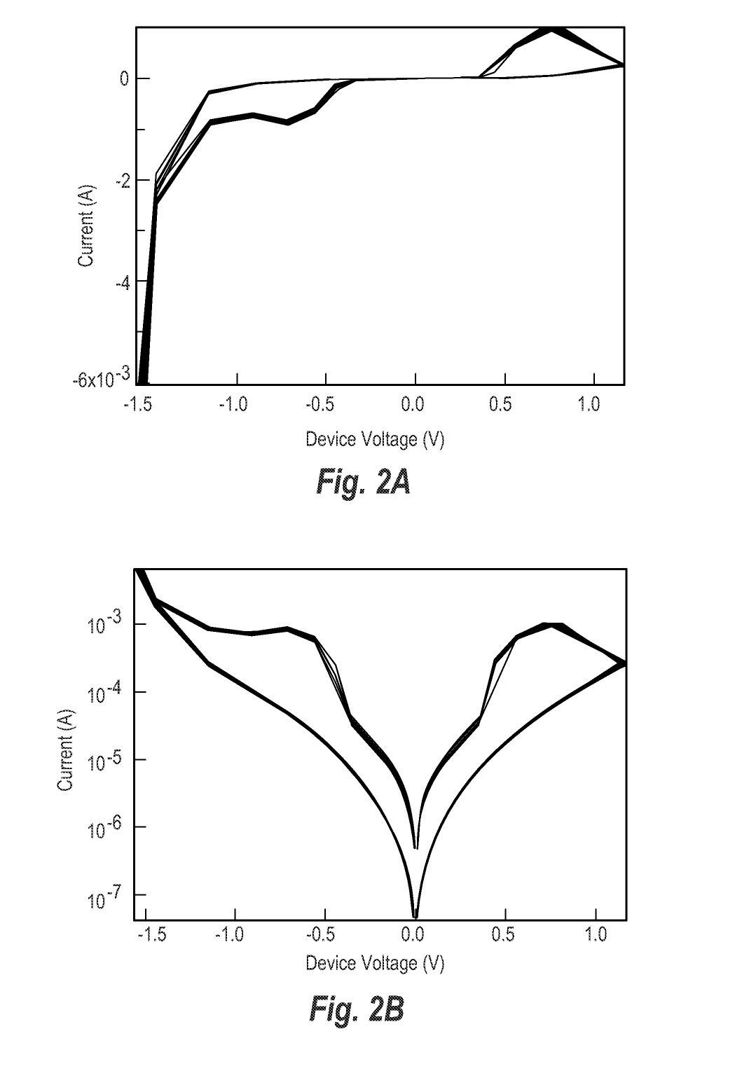

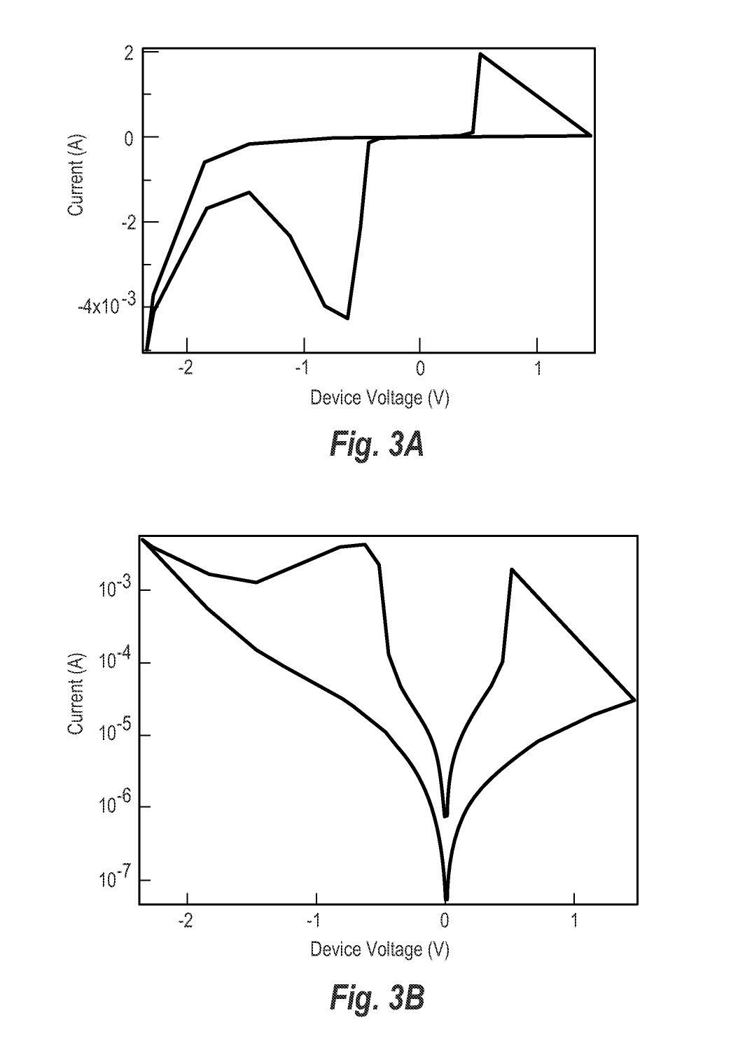

In accordance with the teachings herein, a nonlinear memristor is provided. Examples of the device are depicted in FIGS. 1A-1C. As shown in each of the three figures, the device 100 comprises a bottom, or first, electrode 102, an insulator layer 104, and a top, or second, electrode 106.

The device further includes a switching channel 108 within the insulator layer 104 and extending from the bottom electrode 102 toward the top electrode 106. The switching channel 108 forms a switching interface 110 with the bottom electrode 102. Although one switching channel 108 is shown, there may be more than one switching channel present, although even at a point of time, typically one channel dominates the switching.

The switching channel 108 does not contact the top electrode 106, and instead stops short, leaving a region. As shown in FIG. 1A, the region between the top of the switching channel 108 and the top electrode 106 is occupied by a nano-cap layer 112 of a metal-insulator-transition material. The top electrode 106 is seen to contact both the nano-cap layer 112 and the insulator layer 104 that surrounds the nano-cap layer and the conducting channel 108.

In the formation of the nano-cap layer 112, growth advances along a growth front, denoted 114, from the top electrode 106 into the conducting channel 108. Growth of the nano-cap layer 112 may be limited by diffusion of metal (cation) from the top electrode 106 through the nano-cap layer.

FIG. 1B depicts another example for the formation of the nano-cap layer 112. In this example, the conducting channel 108 extends from the bottom electrode 102 to the top electrode 106, and the nano-cap layer 112 is formed by diffusion of oxygen from the conducting channel into the top electrode, along a growth front 114′. In this example, growth of the nano-cap layer 112 may be limited by diffusion of oxygen (anion) through the nano-cap layer.

FIG. 1C depicts yet another example for the formation of the nanocap layer 112. In this example, the conducting channel 112 is essentially a combination of the growth mechanisms depicted in FIGS. 1A and 1B, with metal (cation) diffusing from the top electrode 106 into the conducting channel 108 and oxygen diffusing from the conducting channel into the top electrode, along growth fronts 114a and 114b, respectively. Both the metal and the oxygen diffuse under their own chemical potential gradients. A “mushroom-shaped” structure may be formed.

Examples of electrode materials for the bottom electrode may include, but are not limited to, platinum (Pt), aluminum (Al), copper (Cu), gold (Au), molybdenum (Mo), niobium (Nb), palladium (Pd), ruthenium (Ru), ruthenium oxide (RuO₂), silver (Ag), tantalum (Ta), tantalum nitride (TaN), titanium nitride (TiN), tungsten (W), and tungsten nitride (WN).

Any of the metal oxides commonly employed for memristor devices may be used as the insulator layer 104. In some examples, the insulator layer 104 may include a transition metal oxide, such as tantalum oxide, titanium oxide, yttrium oxide, hafnium oxide, zirconium oxide, or other like oxides, or may include a metal oxide, such as aluminum oxide, calcium oxide, or magnesium oxide, or other like oxides. In other examples, the material of the insulating layer 104 may be ternary oxides, quaternary oxides, or other complex oxides, such as strontium titanate oxide (STO) or praseodymium calcium manganese oxide (PCMO).

In some examples, the insulator layer 104 may be TaOₓ, where x ranges from about 2 to 2.5. In other examples, the insulator layer may be HfOₓ, where y ranges from about 1.5 to 2. Both of these oxides (TaOₓ and HfOₓ) have exhibited excellent electrical performance.

The switching channel 108 may be a phase supersaturated with oxygen. However, it is a phase with less oxygen than the insulating oxide layer.

For example, if the insulator layer 104 is TaOₓ, then the switching channel 108 may include a metal phase (tantalum) with supersaturated oxygen, represented as Ta(O). In terms of the formula TaO_{y}, y is less than 2. Likewise, if the insulator layer 104 is HfOₓ, then the switching channel 108 may include a metal phase (hafnium) with supersaturated oxygen, represented as Hf(O). In terms of the formula HfO_{y}, y is less than 1.5.

The supersaturated oxygen phase may be formed by an electrical approach, for example. In the case of the TaOₓ insulating phase, when a voltage is applied, phase separation takes place, forming a phase containing a insulating metal oxide, (close to TaO_{2.5}) and a phase containing metal (here, tantalum) supersaturated with oxygen. Essentially, phase decomposition from the insulating TaOₓ (2<x<2.5) a tantalum oxygen solid solution with supersaturated oxygen in the solution takes place. The same considerations obtain for the HfO₂ phase.

The MIT material of the nano-cap layer 112 may be a high order oxide of a metal that is also as conductive as possible at the switching moment; that is, the metal oxide is electrically conductive at high temperature (T); in other words, the temperature is used to control the switching current such that at high temperature, the oxide becomes conductive. Suitable examples of oxides that evidence these two criteria include Ti₃O₅, Ti₂O₃, VO₂ and NbO₂. By a high order oxide is meant that the phase contains as much oxygen as possible. There are two competing aspects: a desire to have as much oxygen as possible, but also to be as conductive as possible at high temperature (the temperature to which the conduction channel is heated up by Joule heating), yet lower oxygen results in higher conductivity. Thus, VO₂, which has less oxygen than V₂O₅, and NbO₂, which has less oxygen than Nb₂O₅, meet both conditions.

The nonlinear current/voltage relation for passive crossbar applications is improved by incorporating the nano-cap structure, which employs a metal/insulator/transition material (MIT). Specifically, the nano-cap layer 112 may have a composition of either VO₂ or NbO₂. Examples of other suitable oxides include, but are not limited to, Ti₂O₃ and Ti₃O₅. The thickness of the nano-cap layer 112 may be less than 1 nm. In other examples, the thickness of the nano-cap layer 112 may be about one-half the thickness of the insulating layer 104, or about 2 to 50 nm.

The top electrode may be the same metal as the metal oxide comprising the nano-cap layer. So, for example, for a nano-cap layer of VO₂, the top electrode may be V, and for a nano-cap layer of NbO₂, the top electrode may be Nb. For other oxides, such as Ti₂O₃, the top electrode would be the metal of that oxide, in this case Ti or Ti suboxide, such as TiO, etc.

Metal-insulator transitions are transitions from a metal (material with good electrical conductivity of electric charges) to an insulator (material where conductivity of charges is quickly suppressed). These transitions can be achieved by tuning various ambient parameters such as temperature or pressure. In the case of VO₂ or NbO₂, for example, the lower temperature state is insulating and the higher temperature state is conducting. For examples of the non-linear behavior of MIT materials, see, e.g., Alexander Pergament et al, “Switching Effects in Oxides of Vanadium, Nickel, and Zinc”, Journal of International Research Publications: Materials Methods & Technologies, Vol. 2, pp. 17-28 (2007).

Without subscribing to any particular theory, it appears that the nonlinearity of the MIT material of the nano-cap layer 112 contributes to the asymmetrical (nonlinear) I/V behavior of the memristors 100 in the low resistance state via current-controlled negative differential resistance. The small switching channel 108, with a width less than 100 nm or less than 60 nm or less than 20 nm or less than 10 nm or less than 5 nm, along with the very insulative material surrounding the channel, contributes to a low switching current, which results in a low switching energy (typically a picojoule or less).

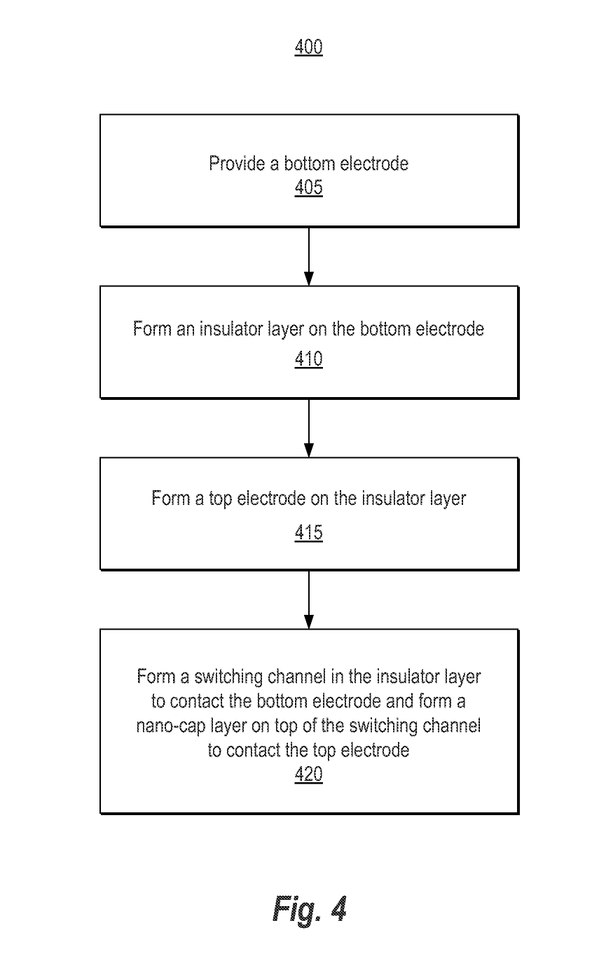

A method 400 of preparing the nonlinear memristor described herein is depicted in FIG. 4. A bottom electrode 102 is provided 405. An insulating layer 104 is formed 410 on the bottom electrode 102. A top electrode 106 is formed 415 on the insulating layer 104. A switching channel 108 is formed 420 in the insulator layer 104 to contact the bottom electrode 102 and essentially simultaneously, a nano-cap layer 112 is formed on top of the switching channel to contact the top electrode 106.

The bottom electrode 102 is provided 405 by any of the common procedures for forming metal electrodes. Examples include, but are not limited to, sputtering, evaporation, ALD (atomic layer deposition), co-deposition, chemical vapor deposition, IBAD (ion beam assisted deposition), or any other film deposition technology. The thickness of the first electrode 102 may be in the range of about 10 nm to a few micrometers.

The insulating layer 104 is formed 410 by any of the common procedures for forming insulating metal oxide layers. Examples include, but are not limited to, deposition by sputtering, atomic layer deposition, chemical vapor deposition, evaporation, co-sputtering (using two metal oxide targets, for example), or other such process. The thickness of the insulating layer 104 may be about 3 to 100 nm.

The top electrode 106 is formed 415 by any of the common procedures for forming metal electrodes, including any of those described above for forming the bottom electrode 102. The thickness of the top electrode 106 may be in the range of about 10 nm to a few micrometers.

The formation 420 of the switching channel 108 and the nano-cap layer 112 may be done in a number of ways. An example of one suitable method includes the electroforming process often used to form switching channels in memristors, namely, the application of a quasi-DC voltage sweep/pulse with limited current. Sweep means a voltage that increases from 0 V to a certain level slowly in a quasi-DC mode; pulse is a very fast voltage pulse, such as 2 V for 100 ns. it can be a current compliance (largest current limit) exerted by the circuit. In some examples, the voltage may sweep from about +2V to −2V and back.

Essentially simultaneously, because the top electrode 106 comprises the metal desired for the metal oxide of the nano-cap layer 112, the voltage sweep causes the formation of the metal oxide to create the nano-cap layer. The switching channel 108 may be the main oxygen source, since it is oxygen oversaturated.

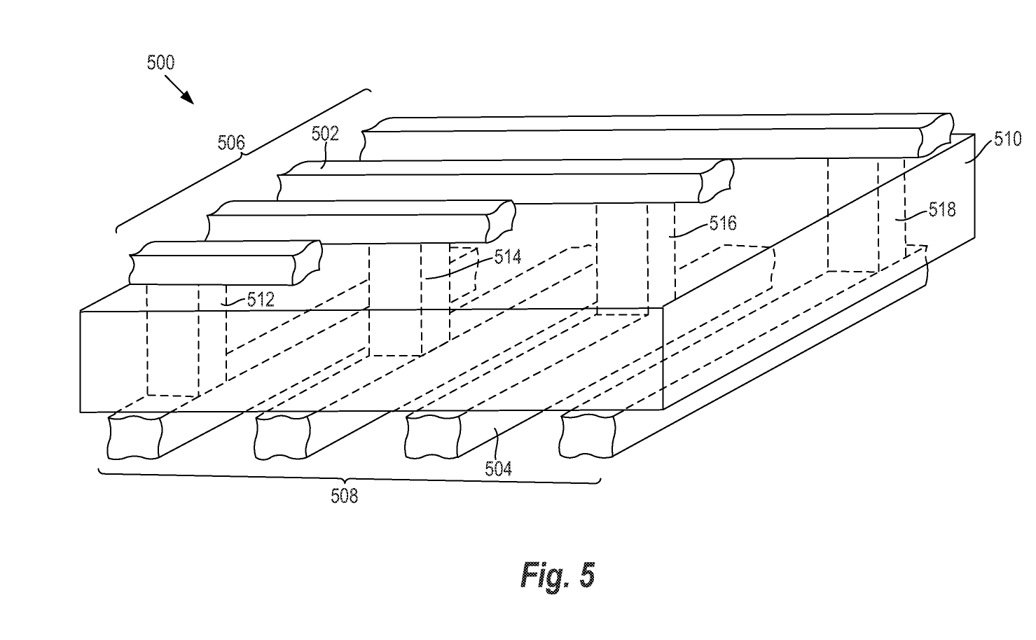

The nonlinear device may be used in a memory array. FIG. 5 shows a perspective view of a nanowire memory array, or crossbar, 500, revealing an intermediate layer 510 disposed between a first layer of approximately parallel nanowires 508 and a second layer of approximately parallel nanowires 506. The first layer of nanowires may be at a non-zero angle relative to the second layer of nanowires.

According to one illustrative example, the intermediate layer 510 may be a dielectric layer. A number of the nonlinear devices 512-518 may be formed in the intermediate layer 510 at the intersections, or junctions, between nanowires 502 in the top layer 506 and nanowires 504 in the bottom layer 508. The nanowires may serve as the upper and lower conductive layers 106, 102, respectively, in the nonlinear device 100. For example, when forming a nonlinear device similar to the example shown in FIGS. 1A-1C, the wires in the top layer 506 could be formed from vanadium or niobium, depending on the metal used to form the nano-cap layer 112, and the nanowires in the bottom layer 508 could be formed from platinum. The upper nanowires would then serve as the top electrode 106 and the lower nanowires would serve as the bottom electrode 102. Alternatively, other conductive materials may be used as the upper and lower nanowires 502 and 504.

For purposes of illustration, only a few of the nonlinear devices 512-518 are shown in FIG. 5. Each of the combined devices 512-518 may be used to represent one or more bits of data. For example, in the simplest case, a nonlinear device may have two states: a conductive state and a nonconductive state. The conductive state may represent a binary “1” and the nonconductive state may represent a binary “0”, or visa versa. Binary data can be written into the nanowire memory array 500 by changing the conductive state of the memristive matrix within the nonlinear devices. The binary data can then be retrieved by sensing the conductive state of the nonlinear devices 512-518.

The example above is only one illustrative example of the nanowire memory array 500. A variety of other configurations could be used. For example, the memory array 500 can incorporate nonlinear elements that have different structures. The different structures could include more or less layers, layers that have different compositions than described above, and layers that are ordered in different ways than shown in the example given above. For example, the memory array could include memristors, memcapacitors, meminductors, or other memory elements. Further, the memory array could use a wide range of conductors to form the crossbars.

It should be understood that the memristors described herein, such as the example memristor depicted in FIG. 1, may include additional components and that some of the components described herein may be removed and/or modified without departing from the scope of the memristor disclosed herein. It should also be understood that the components depicted in the Figures are not drawn to scale and thus, the components may have different relative sizes with respect to each other than as shown therein. For example, the upper, or second, electrode 106 may be arranged substantially perpendicularly to the lower, or first, electrode 102 or may be arranged at some other non-zero angle with respect to each other. As another example, the insulating layer 104 may be relatively smaller or relatively larger than either or both electrode 102 and 106.

Advantageously, excellent electrical performance is obtained, as seen from the experimental results. The process is relatively easy to implement, and at relatively low cost.

What is claimed is:

1. A nonlinear memristor including:
a bottom electrode;
a top electrode;
an insulator layer between the bottom electrode and the top electrode, the insulator layer comprising a metal oxide;
a switching channel within the insulator layer, extending from the bottom electrode toward the top electrode; and
a nano-cap layer of a metal-insulator-transition material between the switching channel and the top electrode,
wherein the top electrode comprises the same metal as the metal in the metal-insulator-transition material.

2. The nonlinear memristor of claim 1, wherein the insulator layer comprises a metal oxide selected from the group consisting of TaOₓ, where x is within a range of about 2 to 2.5, and HfO_{y}, where y is within a range of about 1.5 to 2.

3. The nonlinear memristor of claim 1, wherein the switching channel is a phase with less oxygen than the metal oxide comprising the insulating layer.

4. The nonlinear memristor of claim 3 wherein the insulator layer is TaOₓ, where x is within a range of 2 to 2.5, and wherein the switching channel is Ta-oxygen solid solution with supersaturated oxygen.

5. The nonlinear memristor of claim 3 wherein the insulator layer is HfOₓ, where x is within a range of 1.5 to 2, and wherein the switching channel is Hf-oxygen solid solution with supersaturated oxygen.

6. The nonlinear memristor of claim 1, wherein the metal-insulator-transition material of the nano-cap layer is a high order oxide of a metal that is also as conductive as possible at the switching moment.

7. The nonlinear memristor of claim 6, wherein the metal-insulator-transition material of the nano-cap layer is VO₂ and the top electrode is either V or VOₓ, where 0<x<2.

8. The nonlinear memristor of claim 6, wherein the metal-insulator-transition material of the nano-cap layer is NbO₂ and the top electrode is either Nb or NbOₓ, where 0<x<2.

9. The nonlinear memristor of claim 6, wherein the metal-insulator-transition material of the nano-cap layer is either Ti₃O₅ or Ti₂O₃ and the top electrode is either Ti or TiOₓ, where 0<x<1.5.

10. The nonlinear memristor of claim 1 wherein the switching channel has a width of less than about 100 nm and the nano-cap layer has a thickness less than about 50 nm.

11. The nonlinear memristor of claim 1, wherein the bottom electrode is selected from the group consisting of platinum, aluminum, copper, gold, molybdenum, niobium, palladium, ruthenium, ruthenium oxide, silver, tantalum, tantalum nitride, titanium nitride, tungsten, and tungsten nitride.

12. A method of forming the nonlinear memristor of claim 1, including:
providing the bottom electrode;
forming the insulator layer on the bottom electrode;
forming the top electrode on the insulator layer; and
forming the switching channel in the insulator layer and the nano-cap layer on top of the switching channel.

13. The method of claim 12 wherein the switching channel and the nano-cap layer are formed by an electrical operation process comprising the application of a voltage sweep/pulse with limited current.

14. The method of claim 13 wherein the switching channel and the nano-cap layer are formed by an electroforming process.

15. A crossbar comprising an array of approximately first nanowires and an array of approximately second nanowires, the array of first nanowires crossing the array of second nanowires at a non-zero angle, each intersection of a first nanowire with a second nanowire forming a junction, with the nonlinear memristor of claim 1 at each junction, sandwiched between a first nanowire and a second nanowire.
